(19) United States
(12) Patent Application Publication
(10) Pub. No.: US 2011/0157787 A1
(43) Pub. Date: Jun. 30, 2011

(54) HINGE ASSEMBLY FOR FOLDABLE ELECTRONIC DEVICE

(75) Inventors: Chao DUAN, Shenzhen City (CN); Zhi-Yu HU, Shenzhen City (CN); Chia-Hua CHEN, Shindian (TW)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/872,117

(22) Filed: Aug. 31, 2010

(30) Foreign Application Priority Data
Dec. 31, 2009 (CN) 200910312933.3

(51) Int. Cl. H05K 7/00; E05F 1/12; E05D 11/00

(52) U.S. Cl. 361/679.01; 16/303; 16/250

(57) ABSTRACT

A hinge assembly includes a shaft, a seat made of plastic, a follower, a cam, a latching member and a resilient member. The follower includes a cam surface. The seat is fixed to the follower, and the seat and the follower are placed around the shaft. The cam has a latching cam surface, the cam surface being engaged with the cam latching surface. The latching member is fixed to the cam, and the cam and the latching member are placed around the shaft. The resilient member is placed around the shaft and provides an elastic force to make the cam surface abut against the latching cam surface.

### BACKGROUND

1. Technical Field

The present disclosure relates to hinge assemblies and, particularly, to a hinge assembly for foldable electronic devices such as mobile phones, portable computers, and so on.

2. Description of Related Art

At present, perhaps the most popular portable electronic device in the marketplace is the foldable mobile phone, which generally includes a cover section and a body section. The cover section and the body section are rotatably interconnected through a hinge assembly, for switching the telephone between an in-use position and a closed position.

One kind of hinge assembly employs a cam and a follower made of metal. Although the hinge assembly may achieve the opening and closing of the foldable electronic device, the hinge assembly may be noisy during rotation. If the cam and the follower are made of plastic, although volume of the noise may be reduced, the cam and the follower will more easily break.

Therefore, there is room for improvement within the art.

### BRIEF DESCRIPTION OF THE DRAWINGS

Many aspects of the present hinge assembly can be better understood with reference to the following drawings. The components in the drawings are not necessarily drawn to scale, the emphasis instead being placed upon clearly illustrating the principles of the present hinge assembly. Moreover, in the drawings, like reference numerals designate corresponding parts throughout the several views.

FIG. 1 is an exploded, isometric view of a hinge assembly.

FIG. 2 is similar to FIG. 1, but shown from another aspect.

FIG. 3 is an enlarged, isometric view of a cam and a follower in FIG. 1.

FIG. 4 is an assembled view of the hinge assembly shown in FIG. 1.

FIG. 5 is a cross-sectional view of FIG. 4 taken along line V-V.

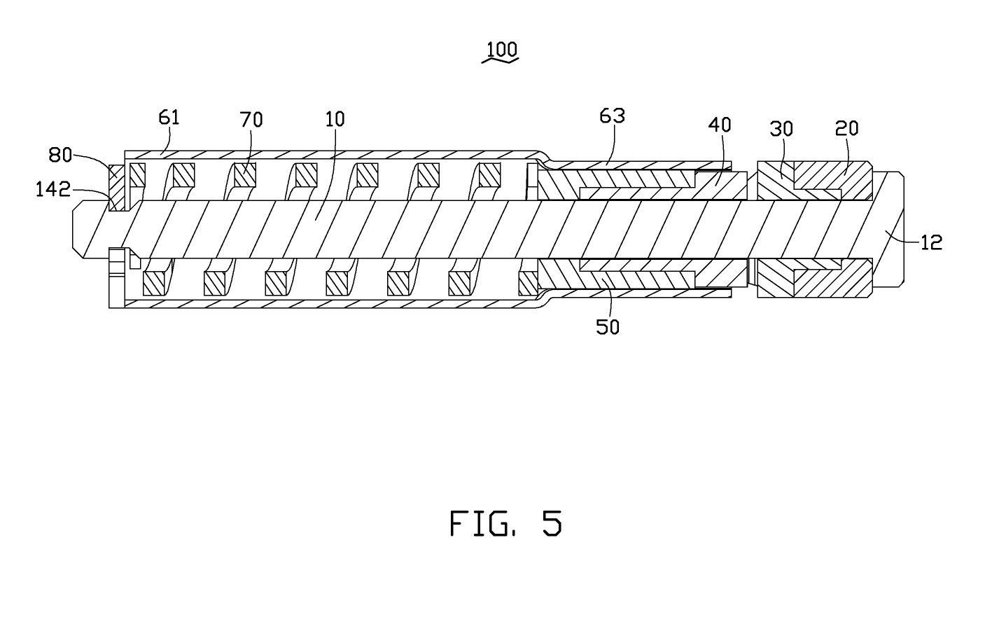

### DETAILED DESCRIPTION

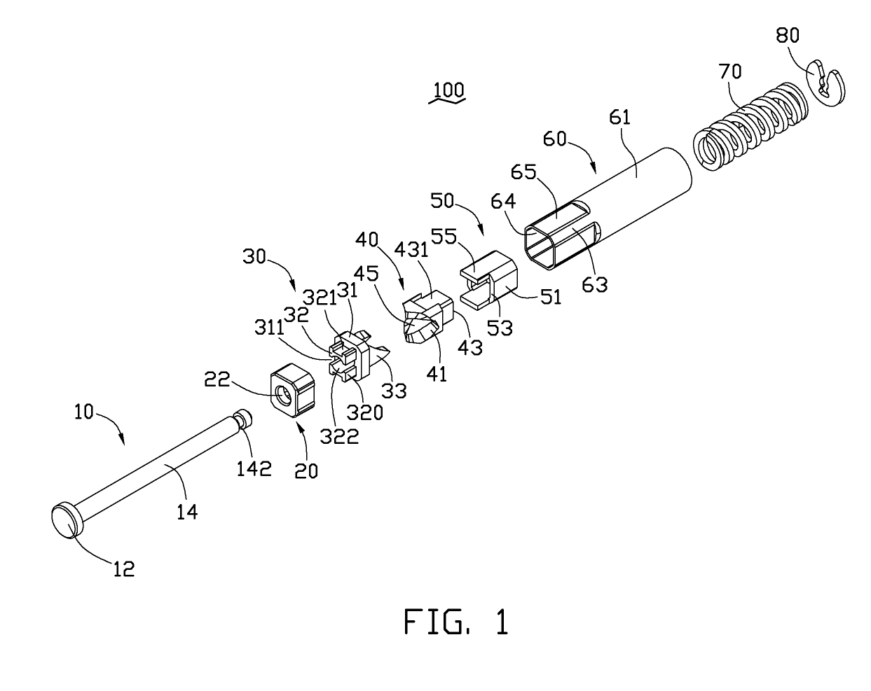

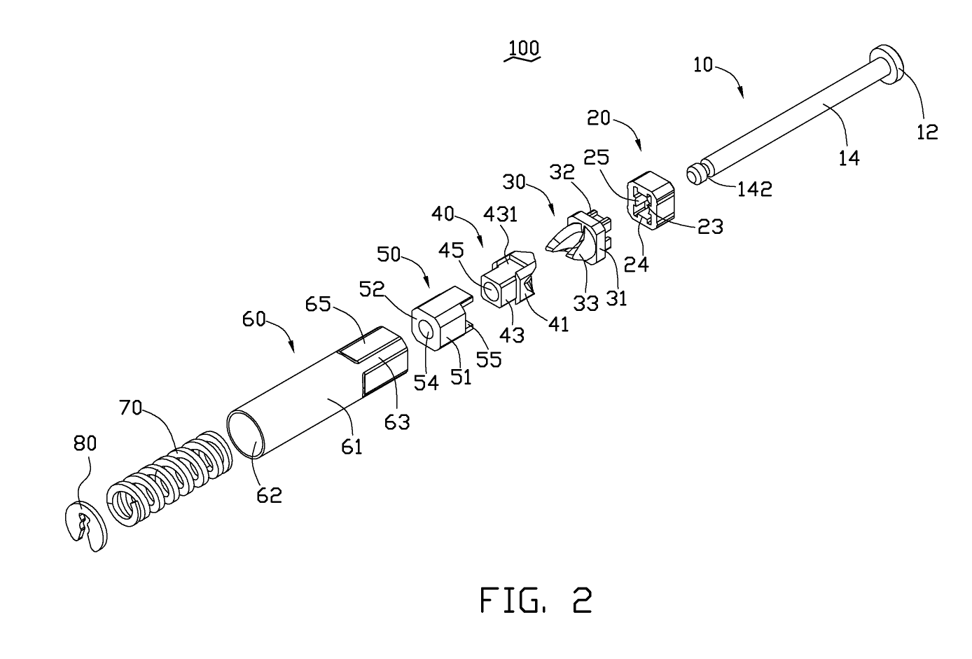

FIGS. 1 and 2 show a hinge assembly 100 according to an exemplary embodiment of the present hinge system. The hinge assembly 100 includes a main shaft 10, a seat 20, a follower 30, a cam 40, a latching member 50, a sleeve 60, a resilient member 70, and a washer 80.

The main shaft 10 coaxially includes a head portion 12 and a shaft portion 14. The shaft portion 14 extends from one end of the head portion 12 and has a smaller diameter than the diameter of the head portion 12. A free end of the shaft portion 14 defines a ring groove 142.

The seat 20 is made of plastic, and is substantially a rectangular parallelepiped. A circular hole 22 is defined at one side of the seat 20, and a square latching hole 23 is defined at another side thereof. The hole 22 communicates with the latching hole 23. A block 24 extends into the latching hole 23 from each of four sidewalls. Two arcuate surfaces 25 are respectively formed on opposite sides of two of the blocks 24 toward a center of the seat 20. The seat 20 is configured for engaging with a body section of a foldable electronic device.

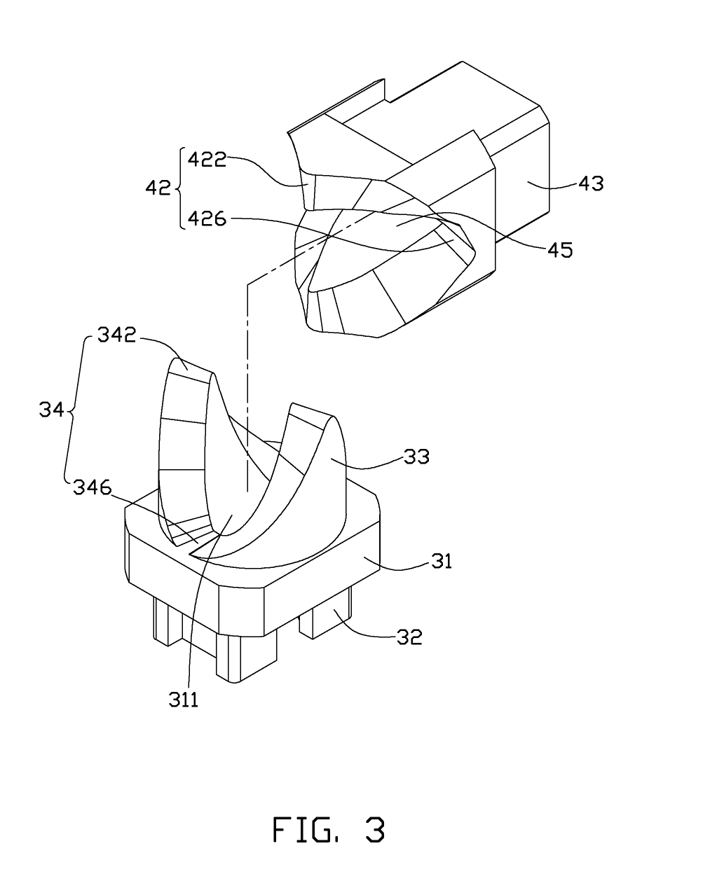

Referring to FIG. 3, the follower 30 is made of metal, and includes a main portion 31, and a fixing portion 32 and a cam portion 33 integrally formed together. The main portion 31 has a shape corresponding to the seat 20. The fixing portion 32 is formed at one side of the main portion 31. The cam portion 33 is formed at another side of the main portion 31. The follower 30 defines a through hole 311. The through hole 311 communicates the fixing portion 32 with the cam portion 33. The shaft portion 14 may be received in the circular hole 22, the latching hole 23 and the through hole 311, and the head portion 12 may abut against the seat 20. The fixing portion 32 includes two opposite ribs 320. Each rib 320 is substantially I-shaped, and each of opposite outside sides of the ribs 320 defines a groove 321. Each of opposite inside sides of the ribs 320 defines an arcuate recess 322. When the seat 20 is latched to the cam 30, two opposite blocks 24 are latched into the grooves 321. Another two blocks 24 are disposed between the ribs 320. The arcuate surface 25 and an inside surface of the arcuate recess 322 surround a space to receive the shaft portion 14. The cam portion 33 includes at least one, e.g. two symmetric first cam surfaces 34. Each first cam surface 34 includes a peak 342 and a valley 346. A plurality of sub-surfaces is formed between the peak 342 and the valley 346. The peak 342 is formed at a highest position of the first cam surface 34. The valley 346 is formed at a lowest position of the first cam surface 34.

The cam 40 is made of metal, and includes a latching cam portion 41 and an end portion 43 extending from the latching cam portion 41. A longitudinal passage 45 is defined in the cam 40 for receiving the shaft portion 14. The latching cam portion 41 includes second cam surfaces 42 for engaging with the first cam surfaces 34 of the follower 30. There is one second cam surface 42 for each first cam surface 34. Each second cam surface 42 includes a peak 422 and a valley 426. A plurality of sub-surfaces is formed between the peak 422 and the valley 426. The end portion 43 is smaller radially than the latching cam portion 41. At least one, e.g. two latching grooves 431 are symmetrically formed on an outer periphery of the end portion 43.

The latching member 50 includes a hollow polygonal can 51, a partially closed end 52 and an open end 53. The partially closed end 52 is opposite to the open end 53. Two extending portions 55 are formed on the open end 53 for being received in the latching grooves 431 to latch the latching member 50 to the cam 40. The partially-closed end 52 has a central hole 54.

The sleeve 60 is substantially a hollow cylinder, and includes a cylindrical body 61 and a positioning portion 63 integrally formed together. The sleeve 60 includes a first open end 62 and a second open end 64 opposite to each other. The positioning portion 63 extends from the second open end 64. At least one flattened surface 65 is formed on an outer peripheral wall of the positioning portion 63. The flat surface portions 63 are configure for engaging with a cover section of the foldable electronic device. In this exemplary embodiment, the sleeve 60 is formed by a punch stretch process. The cylindrical body 61 is fully circular, and has a larger cross-section compared to the cross section of the positioning portion 63 owing to the flat surfaces 65. The number of flat surfaces 65 corresponds to the number of planar surfaces of the polygonal can 51.

The resilient member 70 is preferably made of metal and is spiral-shaped (i.e. a coil spring). The resilient member 70 is just large enough to be placed around the main shaft 10. The resilient member 70 is smaller than the cylindrical portion 61, and is larger than the positioning portion 63.

The washer 80 is made of made of a strong material, such as metal. In the present embodiment, the washer 80 is substantially C-shaped and is clasped in the ring groove 142, thereby mounted with the main shaft 10.

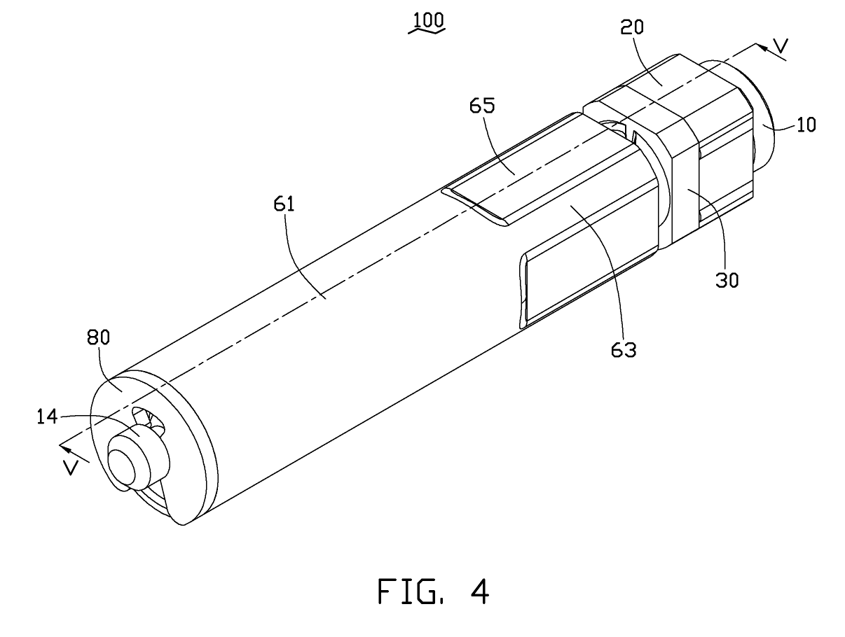

Referring to FIG. 4, the fixing portion 32 is inserted into the latching hole 23 of the seat 20. Two opposite blocks 24 are latched into the grooves 321. Another two blocks 24 are disposed between the ribs 320. Accordingly, the seat 20 is latched to the follower 30 in any manner that will not allow them to rotate relative to one another. The extending portions 55 of the latching member 50 are latched into the latching grooves 431 to latch the latching member 50 to the cam 40. Then, the follower 30 with the seat 20, and the cam 40 with the latching member 50 are mounted on the shaft 10. The head portion 12 abuts against the seat 20. The second cam surface 42 of the cam 40 engages with the first cam surface 34 of the follower 30. After that, the shaft 10 with the above elements is received in the sleeve 60 from the second end 64. The polygonal can 51 engages with the positioning portion 63. The resilient member 70 is assembled into the sleeve 60 from the first open end 62, and is placed around the shaft portion 14. One free end the main shaft 10 passes through the first open end 62, and the washer 80 is mounted in the ring groove 142. One end of the resilient member 70 abuts against the washer 80, and the other end of the resilient member 70 abuts against the latching member 50. Thus, the hinge assembly 100 is integrated into a complete unit.

The hinge assembly 100 is used to interconnect a main body and a cover of the foldable electronic device. The seat 20 non-rotatably engages the main body, and the sleeve 60 non-rotatably engages with the cover.

When the cover is closed relative to the main body, the peaks 422 of the second cam surface 42 abut against the first cam surface 34. The resilient member 70 is compressed to enable the cover and the main body to be in an original closed, stable state.

To open the foldable electronic device, the cover is manually rotated away from the main body, hence the sleeve 60 and the cam 40 rotate relative to the follower 30. The peaks 422 of the second cam surface 42 slide along the first cam surface 34, and the resilient member 70 is compressed further. When the cover is opened to a predetermined angle, the peaks 422 slide over the peaks 342 of the first cam surfaces 34. At the same time, the resilient member 70 is almost completely compressed. Then, when the cover is released, the follower 30 automatically rotates relative to the cam 40 due to the expansion of the resilient member 70 as the peaks 342 slide down along the second cam surface 42. Thus, the cover is automatically rotated to a fully and stable open state. The process of closing the cover is reverse to the process of opening the cover. Since the seat 20 and the latching member 50 are made of plastic, the hinge assembly 100 makes relatively little noise. In addition, only one part of the sleeve 60 forms flattened surfaces, thus the cylindrical body 61 may be made larger to receive the resilient member 70 without adding to the overall bulk of the hinge assembly 100.

It should be understood that the cam portions of follower 30 and the cam 30 may have other shapes. The shape of the cam portion may be changed according to the desired open angle of the cover. The washer 80 may be soldered to the shaft 10. The head portion 12 may be integrally attached with the main shaft 10.

The seat 20 and the follower 30, the cam 40 and the latching member 50 may be formed in any manner that does not allow them to rotate relative to one another. For example, they can be integrally formed together by insert molding.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A hinge assembly comprising:
a shaft;
a seat made of plastic;
a follower including a cam surface, the seat being fixed to the follower, the seat and the follower placed around the shaft;
a cam having a latching cam surface, the cam surface being engaged with the cam latching surface;
a latching member fixed to the cam, the cam and the latching member placed around the shaft;
a resilient member being placed around the shaft and providing an elastic force to make the cam surface abut against the latching cam surface.

2. The hinge assembly as claimed in claim 1, further comprising a sleeve, the sleeve includes a cylindrical portion and a positioning portion, the latching member slidably engages with the positioning portion, and the resilient member is received in the cylindrical portion.

3. The hinge assembly as claimed in claim 2, wherein the sleeve includes a first open end and a second open end, the positioning portion includes at least one flatten surface, the flatten surface extends from the second open end to a part of the sleeve.

4. The hinge assembly as claimed in claim 1, wherein the seat defines a circular hole and a latching hole communicates with each other, and the cam includes a fixing portion received in the latching hole.

5. The hinge assembly as claimed in claim 4, wherein the seat includes a plurality of blocks extending into the latching hole, the fixing portion includes a plurality of grooves, and the blocks are latched into the grooves.

6. The hinge assembly as claimed in claim 1, wherein the cam includes a plurality of latching grooves, the latching member includes two extending portions received in the latching grooves to latch the latching member to the cam.

7. A foldable electronic device having at least two components hinged together by a hinge assembly, the hinge assembly comprising:
a shaft;
a seat made of plastic engaging with one of the components;
a follower including a cam surface, the seat being fixed to the follower, the seat and the follower placed around the shaft;
a cam having a latching cam surface, the cam surface being engaged with the cam latching surface;
a latching member fixed to the cam, the cam and the latching member placed around the shaft, the latching member engaging with the other of the components; and
a resilient member being placed around the shaft and providing an elastic force to make the cam surface abut against the latching cam surface.

8. The foldable electronic device as claimed in claim 7, wherein further comprising a sleeve, the sleeve includes a cylindrical portion and a positioning portion, the latching member slidably engages with the positioning portion, and the resilient member is received in the cylindrical portion.

9. The foldable electronic device as claimed in claim 8, wherein sleeve includes a first open end and a second open end, the positioning portion includes at least one flatten surface, the flatten surface extends from the second open end to a part of the sleeve.

10. The foldable electronic device as claimed in claim 7, wherein the seat defines a circular hole and a latching hole communicates with each other, and the cam includes a fixing portion received in the latching hole.

11. The foldable electronic device as claimed in claim 10, wherein the seat includes a plurality of blocks extending into the latching hole, the fixing portion includes a plurality of grooves, and the blocks are latched into the grooves.

12. A hinge assembly comprising:
a shaft;
a follower including a plastic part and a metal part non-rotatably and non-slidably assembled to each other;
a cam including a plastic part and a metal part non-rotatably and non-slidably assembled to each other;
a resilient member, the follower, the cam and the resilient being placed around the shaft, and the resilient providing an elastic force to make the cam abut against the follower.

13. The hinge assembly as claimed in claim 12, further comprising a sleeve, the sleeve includes a cylindrical portion and a positioning portion, the plastic part of the cam slidably engages with the positioning portion, and the resilient member is received in the cylindrical portion.
